(19) United States
(12) Patent Application Publication
(10) Pub. No.: US 2012/0252188 A1
(43) Pub. Date: Oct. 4, 2012

(54) PLASMA PROCESSING METHOD AND DEVICE ISOLATION METHOD

(75) Inventors: Ryota YONEZAWA, Nirasaki City (JP); Kazuyoshi Yamazaki, Nirasaki City (JP); Masaki Sano, Nirasaki City (JP)

(73) Assignee: TOKYO ELECTRON LIMITED, Tokyo (JP)

(21) Appl. No.: 13/432,151

(22) Filed: Mar. 28, 2012

(30) Foreign Application Priority Data
Mar. 31, 2011 (JP) 2011-080076

(51) Int. Cl. H01L 21/762; H01L 21/318

(52) U.S. Cl. 438/437; 438/776; 257/E21.546; 257/E21.293

(57) ABSTRACT

A plasma processing method for use in device isolation by shallow trench isolation in which an insulating film is embedded in a trench formed in silicon and the insulating film is planarized to form a device isolation film, the method includes a plasma nitriding the silicon of an inner wall surface of the trench by using a plasma before embedding the insulating film in the trench. The plasma nitriding is performed by using a plasma of a processing gas containing a nitrogen-containing gas under conditions in which a processing pressure ranges from 1.3 Pa to 187 Pa and a ratio of a volumetric flow rate of the nitrogen-containing gas to a volumetric flow rate of the entire processing gas ranges from 1% to 80% such that a silicon nitride film is formed on the inner wall surface of the trench to have a thickness of 1 to 10 nm.

### CROSS-REFERENCE TO RELATED APPLICATIONS

This application claims priority to Japanese Patent Application No. 2011-080076 filed on Mar. 31, 2011, the entire content of which is incorporated herein by reference.

### FIELD OF THE INVENTION

The present invention relates to a plasma processing method and a device isolation method that can be used when forming a device isolation structure of various semiconductor devices.

### BACKGROUND OF THE INVENTION

As a technique for isolating an element formed on a silicon substrate, shallow trench isolation (STI) has been known. STI is carried out by etching silicon to form a trench, embedding therein a SiO₂ film serving as a device isolation film, and performing planarization by chemical mechanical polishing (CMP).

In STI, a thin insulating film is formed along an inner wall surface of the trench before embedding the SiO₂ film in the trench. This insulating film is formed for the purpose of preventing oxygen in a reaction gas from diffusing into the silicon when embedding the SiO₂ film in the trench in a subsequent process. That is, the insulating film thinly formed along the inner wall surface of the trench functions as a kind of barrier film against diffusion of oxygen.

In STI, as a technique for forming a thin insulating film on a wall surface of a trench, for example, Japanese Patent Application Publication No. 2008-41901 discloses a process for forming a silicon nitride film having a thickness of 10 to 20 nm on an inner wall surface of a trench by a deposition method. Further, International Publication No. WO2007/136049 discloses a process for forming a silicon oxide film containing nitrogen at a concentration of 1 wt % or less by plasma oxidizing the trench using a plasma of a processing gas containing an oxygen gas and a nitrogen gas. International Publication No. WO2007/136049 discloses merely a technology for forming the silicon oxide film, wherein the nitrogen gas is added in order to promote an oxidation rate of silicon.

With the progress of the miniaturization of semiconductor devices, an element formation region of the device is becoming narrower and an opening width of the trench is also becoming smaller. In the deposition method of Japanese Patent Application Publication No. 2008-41901, it is difficult to form a silicon nitride film as a thin film of about several nm along the inner wall surface of the trench. Further, since the silicon nitride film formed by the deposition method has low denseness, if thinning is performed in response to the miniaturization, there is a problem such that the function of the barrier film is impaired.

### SUMMARY OF THE INVENTION

In view of the above, the present invention provides a method for forming a thin film of a thickness of about several nm, having barrier properties against diffusion of oxygen, along an inner wall surface of a trench of silicon in an STI process.

In accordance with an aspect of the present invention, there is provided a plasma processing method for use in device isolation by shallow trench isolation in which an insulating film is embedded in a trench formed in silicon and the insulating film is planarized to form a device isolation film, the method including: a plasma nitriding the silicon of an inner wall surface of the trench by using a plasma before embedding the insulating film in the trench, wherein the plasma nitriding is performed by using a plasma of a processing gas containing a nitrogen-containing gas under conditions in which a processing pressure ranges from 1.3 Pa to 187 Pa and a ratio of a volumetric flow rate of the nitrogen-containing gas to a volumetric flow rate of the entire processing gas ranges from 1% to 80% such that a silicon nitride film is formed on the inner wall surface of the trench to have a thickness of 1 to 10 nm.

In accordance with another aspect of the present invention, there is provided a device isolation method including: forming a trench in silicon; embedding an insulating film in the trench; planarizing the insulating film to form an device isolation film; and before said embedding the insulating film in the trench, a plasma nitriding an inner wall surface of the trench by using a plasma of a processing gas containing a nitrogen-containing gas under conditions in which a processing pressure ranges from 1.3 Pa to 187 Pa and a ratio of a volumetric flow rate of the nitrogen-containing gas to a volumetric flow rate of the entire processing gas ranges from 1% to 80% such that a silicon nitride film is formed to have a thickness of 1 to 10 nm.

According to the plasma processing method of the present invention, in the plasma process performed for a short period of time, it is possible to form a liner film of a thickness of 1 to 10 nm, having a barrier function against the diffusion of oxygen in a thermal oxidation process at a high temperature, almost without changing the depth or width of the trench formed in the silicon. Thus, in a manufacturing process of various semiconductor devices, by using the plasma processing method of the present invention when the device isolation is performed by STI, thereby increasing reliability of the semiconductor device while responding to miniaturization.

### BRIEF DESCRIPTION OF THE DRAWINGS

The objects and features of the present invention will become apparent from the following description of embodiments, given in conjunction with the accompanying drawings, in which:

FIG. 1 is a cross-sectional view schematically showing an example of a plasma processing apparatus that can be used in a first embodiment of the present invention;

FIG. 2 shows a structure of a planar antenna;

FIG. 3 is an explanatory diagram showing a configuration example of a control unit;

FIGS. 4A and 4B show steps of a plasma processing method in accordance with the first embodiment of the present invention, wherein FIG. 4A illustrates a structure of an object to be processed before plasma nitriding, and FIG. 4B illustrates a structure of the object to be processed after plasma nitriding;

FIG. 5 is a cross-sectional view schematically showing an example of a plasma processing apparatus that can be used in a second embodiment of the present invention;

FIGS. 6A to 6C show steps of a plasma processing method in accordance with the second embodiment of the present invention, wherein FIG. 6A illustrates a structure of an object to be processed before plasma nitriding, FIG. 6B illustrates a structure of the object to be processed after plasma nitriding, and FIG. 6C illustrates a structure of the object to be processed after plasma oxidation;

FIG. 7 is a plan view schematically showing a configuration of a substrate processing system that can be used in the second embodiment of the present invention;

FIG. 8 is a graph showing a relationship between a processing temperature of high temperature thermal oxidation and an amount of increase in film thickness in Experiment 1;

FIG. 9 is a graph showing a relationship between a processing time of plasma nitriding and a film thickness of a SiN film in Experiment 2;

FIG. 10 is a graph showing a relationship between a processing temperature of high temperature thermal oxidation and an amount of increase in film thickness according to the processing time of plasma nitriding in Experiment 2;

FIG. 11 is a graph showing a relationship between a processing pressure of plasma nitriding and an amount of increase in film thickness in Experiment 3;

FIG. 12 illustrates a nitrogen concentration and an oxygen concentration in a SiN film and a SiON film by XPC analysis in Experiment 4;

FIG. 13 is a cross-sectional view showing the vicinity of a surface of a wafer for explaining procedures for forming a device isolation structure by an STI process;

FIG. 14 is a cross-sectional view showing the vicinity of the surface of the wafer in a state where a surface of silicon is exposed;

FIG. 15 is a cross-sectional view showing the vicinity of the surface of the wafer after forming a trench;

FIG. 16 is a cross-sectional view showing the vicinity of the surface of the wafer after forming a liner SiN film (liner SiON film);

FIG. 17 is a cross-sectional view showing the vicinity of the surface of the wafer in a state where a buried insulating film is formed; and

FIG. 18 is a cross-sectional view showing the vicinity of the surface of the wafer with the device isolation structure formed thereon.

### DETAILED DESCRIPTION OF THE EMBODIMENTS

### First Embodiment

Hereinafter, an embodiment of the present invention will be described with reference to the accompanying drawings which form a part hereof. A plasma processing method of this embodiment is preferably applied, in the device isolation using STI (shallow trench isolation) method including embedding an insulating film in a trench formed in silicon and planarizing the insulating film to form a device isolation film, to a case of nitriding the silicon of an inner wall surface of the trench by using a plasma before embedding the insulating film in the trench. The plasma processing method of this embodiment may include a plasma nitriding step of nitriding the inner wall surface of the trench by using a plasma of a processing gas containing a nitrogen-containing gas to form a silicon nitride film having a thickness of 1 to 10 nm before embedding the insulating film in the trench in the STI process. In this case, the silicon may be a silicon layer (single crystalline silicon or polysilicon), or silicon substrate.

<Plasma Processing Apparatus>

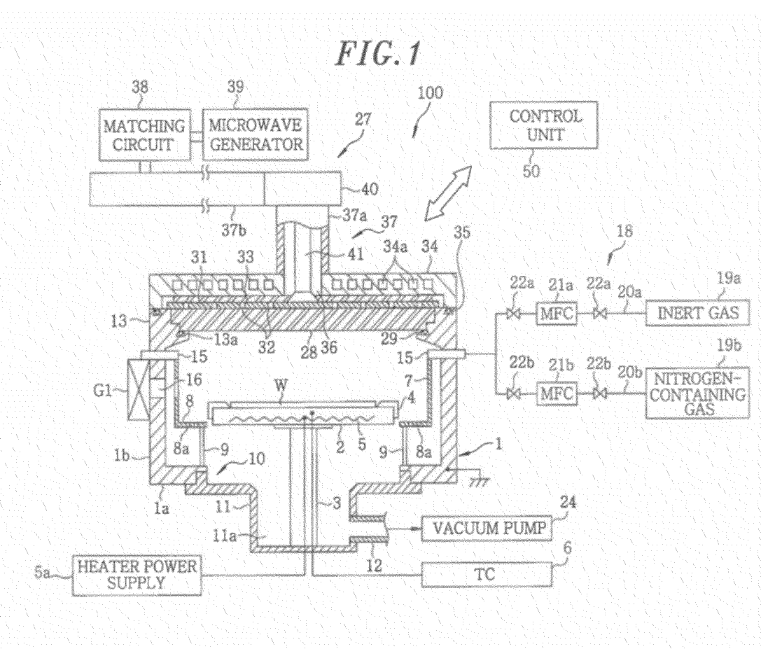

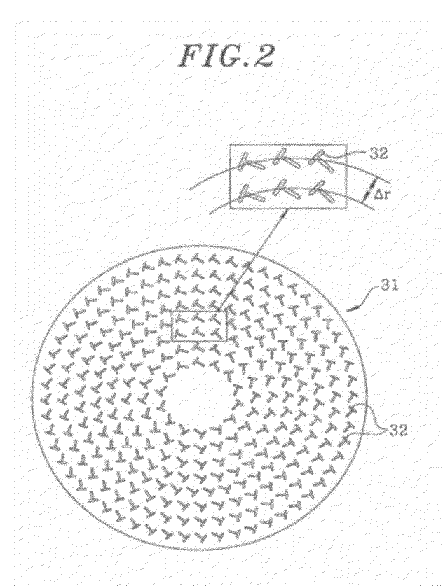

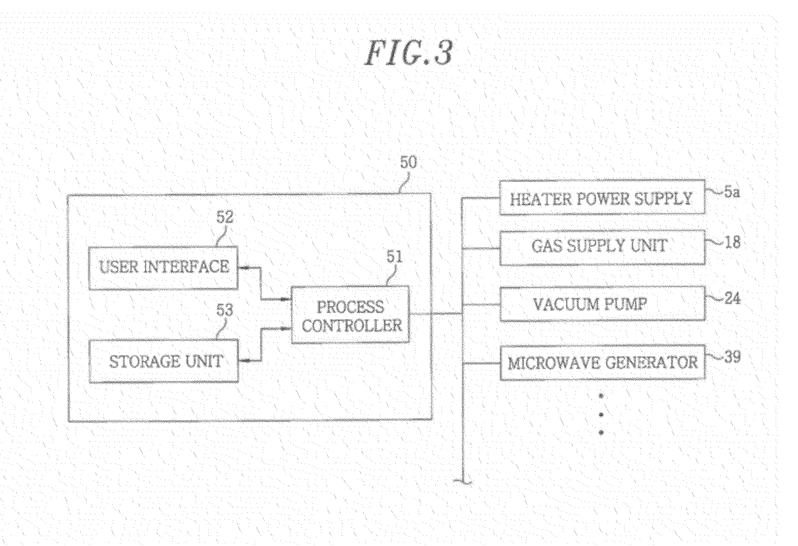

FIG. 1 is a cross-sectional view schematically showing a configuration of a plasma processing apparatus 100 used in a plasma processing method in accordance with a first embodiment. FIG. 2 is a plan view showing a planar antenna of the plasma processing apparatus 100 of FIG. 1. FIG. 3 is a diagram showing a configuration example of a control unit configured to control the plasma processing apparatus 100 of FIG. 1.

The plasma processing apparatus 100 is configured as a RLSA microwave plasma processing apparatus capable of generating a microwave-excited plasma with high density and low electron temperature by introducing a microwave into a processing chamber from a planar antenna having slot-shaped holes, particularly, a radial line slot antenna (RLSA). In the plasma processing apparatus 100, processing can be performed by a plasma with plasma density of 1×10¹⁰ to 5×10¹²/cm³, and low electron temperature of 0.7 to 2 eV. Accordingly, the plasma processing apparatus 100 can be suitably used for the purpose of performing plasma nitriding in a process of manufacturing various semiconductor devices.

The plasma processing apparatus 100 includes, as main elements, a processing chamber 1 which is hermetically sealed, a gas supply unit 18 for supplying a gas into the processing chamber 1, an exhaust unit having a vacuum pump 24 for vacuum evacuating the processing chamber 1, an microwave introducing unit 27 provided at the top of the processing chamber 1 to introduce a microwave into the processing chamber 1, and a control unit 50 for controlling each component of the plasma processing apparatus 100. Further, instead of using the gas supply unit 18 as a component of the plasma processing apparatus 100, an external gas supply unit may be connected to the plasma processing apparatus 100 to perform the supply of gas.

The processing chamber 1 is grounded and formed in a substantially cylindrical shape. Also, the processing chamber 1 may be formed in a substantially square tubular shape. The processing chamber 1 has a bottom wall 1a and a sidewall 1b made of metal such as aluminum or an alloy thereof.

A mounting table 2 for horizontally supporting a semiconductor wafer (hereinafter simply referred to as “wafer”) W serving as an object to be processed is provided in the processing chamber 1. The mounting table 2 is formed of a material with high thermal conductivity, e.g., ceramics such as AlN. The mounting table 2 is supported by a cylindrical support member 3 extending upward from a central bottom portion of an exhaust chamber 11. The support member 3 is made of, e.g., ceramics such as AlN.

Further, a cover ring 4 is provided in the mounting table 2 to cover a peripheral portion of the mounting table 2 and guide the wafer W. The cover ring 4 is an annular member made of, e.g., a material such as quartz, AlN, AlO₃ and SiN. The cover ring 4 is preferably to cover the top surface and side surface of the mounting table 2, thereby preventing metal contamination or the like on the silicon.

Further, a resistance heater 5 is embedded as a temperature adjusting unit in the mounting table 2. The heater 5 is supplied with power from a heater power supply 5a to heat the mounting table 2, thereby uniformly heating the wafer W serving as an object to be processed.

Further, a thermocouple (TC) 6 is provided in the mounting table 2. The temperature of the mounting table 2 is measured by the thermocouple 6 such that the heating temperature of the wafer W can be controlled in a range, e.g., from room temperature to 900° C.

Further, wafer support pins (not shown) for supporting and lifting the wafer W are provided in the mounting table 2. Each of the wafer support pins is provided to protrude from and retreat into the top surface of the mounting table 2.

A cylindrical liner 7 made of quartz is provided on an inner periphery of the processing chamber 1. Further, an annular baffle plate 8 made of quartz and having exhaust holes 8a is provided on an outer peripheral side of the mounting table 2 to uniformly evacuate an inside of the processing chamber 1. The baffle plate 8 is supported by support columns 9.

A circular opening 10 is formed in an approximately central portion of the bottom wall 1a of the processing chamber 1. The exhaust chamber 11 is provided at the bottom wall 1a to protrude downward and communicate with the opening 10. An exhaust pipe 12 is connected to the exhaust chamber 11, and is connected to the vacuum pump 24 via the exhaust pipe 12.

Provided at the top of the processing chamber 1 is a lid member 13 which has an opening at its center and an opening/closing function. Formed on an inner periphery of the opening is an annular support portion 13a to protrude toward the inside (space in the processing chamber).

A gas inlet 15 is annularly provided at the sidewall 1b of the processing chamber 1. The gas inlet 15 is connected to the gas supply unit 18 for supplying a nitrogen-containing gas or plasma excitation gas. Further, the gas inlet 15 may be formed in a nozzle shape or shower shape.

Further, provided in the sidewall 1b of the processing chamber 1 are a loading/unloading port 16 through which the wafer W is loaded/unloaded between the plasma processing apparatus 100 and a vacuum side transfer chamber (not shown) adjacent to the plasma processing apparatus 100, and a gate valve G1 for opening and closing the loading/unloading port 16.

The gas supply unit 18 has gas supply sources (e.g., an inert gas supply source 19a and a nitrogen-containing gas supply source 19b), lines (e.g., gas lines 20a and 20b), flow rate controllers (e.g., mass flow controllers (MFCs) 21a and 21b), and valves (e.g., opening/closing valves 22a and 22b). Further, the gas supply unit 18 may further have, as a gas supply source (not shown) other than the above-mentioned gas supply sources, e.g., a purge gas supply source or the like used when changing the atmosphere in the processing chamber 1.

As an inert gas serving as a plasma generation gas used in the plasma nitriding, e.g., a rare gas or the like may be used. As the rare gas, e.g., Ar gas, Kr gas, Xe gas, He gas or the like may be used. Among them, particularly, Ar gas is preferably used in terms of economic advantages. As a nitrogen-containing gas, e.g., N₂, NO, NO₂, NH₃ or the like may be used.

The inert gas and the nitrogen-containing gas reach the gas inlet 15 from the inert gas supply source 19a and the nitrogen-containing gas supply source 19b of the gas supply unit 18 through the gas lines 20a and 20b respectively, and are introduced into the processing chamber 1 from the gas inlet 15. Provided in the gas line 20a connected to the corresponding gas supply source are the mass flow controller 21a and a pair of the opening/closing valves 22a located at the upstream and downstream sides of the mass flow controller 21a. Similarly, provided in the gas line 20b connected to the corresponding gas supply source are the mass flow controller 21b and a pair of the opening/closing valves 22b located at the upstream and downstream sides of the mass flow controller 21b. By the configuration of the gas supply unit 18, it is possible to switch the supplied gas or control the flow rate.

The exhaust unit has the vacuum pump 24. The vacuum pump 24 is configured as a high speed vacuum pump, e.g., a turbo molecular pump or the like. The vacuum pump 24 is connected to the exhaust chamber 11 of the processing chamber 1 through the exhaust pipe 12. The gas in the processing chamber 1 uniformly flows in a space 11a of the exhaust chamber 11, and the gas is exhausted from the space 11a to the outside through the exhaust pipe 12 by operating the vacuum pump 24. Accordingly, an internal pressure of the processing chamber 1 can be rapidly reduced to a predetermined vacuum level of, e.g., 0.133 Pa.

Next, a configuration of the microwave introducing unit 27 will be described. The microwave introducing unit 27 includes, as main elements, a microwave transmitting plate 28, a planar antenna 31, a wave retardation member 33, a cover member 34, a waveguide 37, a matching circuit 38 and a microwave generator 39.

The microwave transmitting plate 28 transmitting a microwave is disposed on the support portion 13a protruding inward in the lid member 13. The microwave transmitting plate 28 is formed of a dielectric material, e.g., ceramics such as quartz, Al₂O₃, AlN or the like. A seal member 29 is provided to hermetically seal a gap between the microwave transmitting plate 28 and the support portion 13a, thereby maintaining airtightness of the processing chamber 1.

The planar antenna 31 is disposed above the microwave transmitting plate 28 to face the mounting table 2. The planar antenna 31 has a disc shape. Further, the planar antenna 31 may have, e.g., a rectangular plate shape without being limited to a disc shape. The planar antenna 31 is suspended and fixed on an upper end of the lid member 13.

The planar antenna 31 is formed of, e.g., a gold or silver plated copper plate or aluminum plate. The planar antenna 31 has slot-shaped microwave radiation holes 32 to radiate the microwave. The microwave radiation holes 32 are formed in a specific pattern to pass through the planar antenna 31.

Each of the microwave radiation holes 32 has, e.g., an elongated rectangular shape (slot shape) as shown in FIG. 2. Further, generally, the microwave radiation holes 32 adjacent to each other are arranged in a “T” shape. The microwave radiation holes 32 combined and arranged in a specific shape (e.g., T shape) are arranged as a whole in a concentric circular pattern.

The length and arrangement interval of the microwave radiation holes 32 are determined according to the wavelength (λg) of the microwave in the waveguide 37. For example, the microwave radiation holes 32 are arranged such that the arrangement interval ranges from λg/4 to λg. Further, in FIG. 2, the arrangement interval between the microwave radiation holes 32 adjacent to each other in the concentric circular pattern is represented by Δr. Further, the microwave radiation holes 32 may have other shapes such as circular shape and circular arc shape. Moreover, the microwave radiation holes 32 may be arranged in other patterns, e.g., spiral or radial pattern without being limited to the concentric circular pattern.

The wave retardation member 33 having a larger dielectric constant than the vacuum is disposed on an upper surface of the planar antenna 31. Since the microwave has a longer wavelength in the vacuum, the wave retardation member 33 functions to shorten the wavelength of the microwave to stably adjust the plasma. For example, quartz, polytetrafluoroethylene resin, polyimide resin or the like may be used as a material of the wave retardation member 33.

Further, the planar antenna 31 may be in contact with or separated from the microwave transmitting plate 28, but it is preferable that the planar antenna 31 is in contact with the microwave transmitting plate 28. Further, the wave retardation member 33 may be in contact with or separated from the planar antenna 31, but it is preferable that the wave retardation member 33 is in contact with the planar antenna 31.

The cover member 34 is provided at the top of the processing chamber 1 to cover the planar antenna 31 and the wave retardation member 33. The cover member 34 is formed of a metal material such as aluminum and stainless steel. A flat waveguide is constituted by the cover member 34 and the planar antenna 31. A seal member 35 is provided to seal a gap between an upper end of the lid member 13 and the cover member 34. Further, the cover member 34 has a cooling water passage 34a formed therein. The cover member 34, the wave retardation member 33, the planar antenna 31 and the microwave transmitting plate 28 may be cooled by flowing cooling water in the cooling water passage 34a. Further, the cover member 34 is grounded.

An opening 36 is formed in a central portion of an upper wall (ceiling) of the cover member 34. The opening 36 is connected to the waveguide 37. Connected to the other end of the waveguide 37 is the microwave generator 39 for generating a microwave via the matching circuit 38.

The waveguide 37 includes a coaxial waveguide 37a having a circular cross sectional shape, which extends upward from the opening 36 of the cover member 34, and a rectangular waveguide 37b, which is connected to an upper end portion of the coaxial waveguide 37a via a mode converter 40 and extends in a horizontal direction. The mode converter 40 functions to convert a microwave propagating in a TE (Transverse Electric) mode in the rectangular waveguide 37b into a TEM (Transverse ElectroMagnetic) mode microwave.

An internal conductor 41 extends through the center of the coaxial waveguide 37a. A lower end portion of the internal conductor 41 is connected and fixed to a central portion of the planar antenna 31. By this structure, the microwave is efficiently, uniformly and radially propagated to the flat waveguide constituted by the cover member 34 and the planar antenna 31 through the internal conductor 41 of the coaxial waveguide 37a. Then, the microwave is introduced into the processing chamber from the microwave radiation holes (slots) 32 of the planar antenna 31, thereby generating a plasma.

By the microwave introducing unit 27 having the above configuration, the microwave generated in the microwave generator 39 is propagated to the planar antenna 31 through the waveguide 37, and introduced into the processing chamber 1 through the microwave transmitting plate 28. Further, the microwave preferably has a frequency of, e.g., 2.45 GHz, but the frequency of the microwave may be 8.35 GHz, 1.98 GHz or the like.

Each component of the plasma processing apparatus 100 is connected to and controlled by the control unit 50. The control unit 50 has a computer. For example, as shown in FIG. 3, the control unit 50 includes a process controller 51 having a CPU, and a user interface 52 and a storage unit 53, which are connected to the process controller 51. The process controller 51 is a controller generally configured to control respective components (e.g., the heater power supply 5a, the gas supply unit 18, the vacuum pump 24, the microwave generator 39 and the like) associated with the process conditions such as temperature, pressure, gas flow rate, microwave output and the like in the plasma processing apparatus 100.

The user interface 52 includes a keyboard for allowing a process operator to perform an input operation of commands in order to manage the plasma processing apparatus 100, a display for visually displaying an operational status of the plasma processing apparatus 100, or the like. Further, the storage unit 53 stores a recipe including process condition data or control programs (software) for performing various processes in the plasma processing apparatus 100 under the control of the process controller 51.

Further, if necessary, a certain recipe is retrieved from the storage unit 53 in accordance with instructions inputted through the user interface 52 and executed by the process controller 51. Accordingly, a desired process is performed in the processing chamber 1 of the plasma processing apparatus 100 under the control of the process controller 51. Further, the recipe including process condition data or control programs may be used from those stored in a computer-readable storage medium (e.g., CD-ROM, hard disk, flexible disk, flash memory, DVD, blu-ray disc and the like), or transmitted at any time from other devices via, e.g., a dedicated line to be available online.

In the plasma processing apparatus 100 having the above configuration, a plasma process can be performed at a low temperature equal to or lower than 600° C. without causing damage to a base layer or the like. Further, since the plasma processing apparatus 100 has excellent plasma uniformity, in-plane uniformity of processing may be achieved even on a large-sized wafer W having a diameter of, e.g., 300 mm or more.

<Plasma Processing Method>

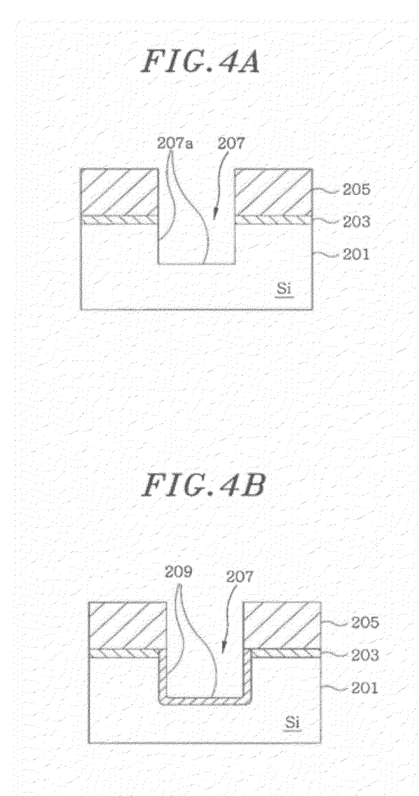

Next, a plasma processing method performed in the plasma processing apparatus 100 will be described with reference to FIGS. 4A and 4B. FIGS. 4A and 4B are cross-sectional views showing the vicinity of the surface of the wafer W for explaining steps of the plasma processing method of this embodiment.

In the plasma processing method of this embodiment, first, the wafer W to be processed is prepared. As shown in FIG. 4A, silicon (silicon layer or silicon substrate) 201, a silicon oxide (SiO₂) film 203, and a silicon nitride (SiN) film 205 are sequentially stacked on the surface of the wafer W. Further, a trench 207 is formed in the silicon 201 of the wafer W. The trench 207 is formed by etching using the SiN film 205 as a mask, and is a portion where a device isolation film is embedded.

Then, an inner wall surface of the trench 207 of the wafer W is plasma nitrided by using the plasma processing apparatus 100. By the plasma nitriding, an inner wall surface 207a of the trench 207 is thinly nitrided, and as shown in FIG. 4B, a liner SiN film 209 is formed. In this case, a thickness of the liner SiN film 209 is preferably in a range, e.g., from 1 nm to 10 nm in order to respond to the miniaturization of semiconductor devices.

<Plasma Nitriding Procedures>

Plasma nitriding procedures are as follows. First, the wafer W to be processed is loaded into the plasma processing apparatus 100, and placed on the mounting table 2. Then, while vacuum evacuating the processing chamber 1 of the plasma processing apparatus 100, e.g., Ar gas and N₂ gas are respectively introduced into the processing chamber 1 at predetermined flow rates from the inert gas supply source 19a and the nitrogen-containing gas supply source 19b of the gas supply unit 18 through the gas inlet 15. Thus, the internal pressure of the processing chamber 1 is adjusted to a predetermined pressure.

Then, the microwave of a predetermined frequency (e.g., 2.45 GHz) generated in the microwave generator 39 is transmitted to the waveguide 37 via the matching circuit 38. The microwave transmitted to the waveguide 37 sequentially passes through the rectangular waveguide 37b and the coaxial waveguide 37a, and is supplied to the planar antenna 31 through the internal conductor 41. That is, the microwave propagates in a TE mode in the rectangular waveguide 37b, and the TE mode microwave is converted into a TEM mode microwave by the mode convertor 40. The TEM mode microwave propagates in the flat waveguide constituted by the cover member 34 and the planar antenna 31 through the coaxial waveguide 37a. Then, the microwave is radiated to the space above the wafer W in the processing chamber 1, through the microwave transmitting plate 28, from the microwave radiation holes 32 formed in a slot shape to pass through the planar antenna 31. The output of the microwave may be selected according to the purpose in a range from 1000 W to 5000 W in case of processing the wafer W having a diameter of, e.g., 200 mm or more.

An electromagnetic field is formed in the processing chamber 1 by the microwave radiated into the processing chamber 1 from the planar antenna 31 through the microwave transmitting plate 28, and the Ar gas and N₂ gas are converted into a plasma respectively. In this case, the microwave is radiated from the microwave radiation holes 32 of the planar antenna 31, thereby generating a plasma having a high density of approximately 1×10¹⁰ to 5×10¹²/cm³ and a low electron temperature of approximately 1.2 eV or less in the vicinity of the wafer W. In case of using the plasma generated as described above, it is possible to reduce damage to a base film due to ions or the like in the plasma. Further, a plasma nitriding process is performed on the silicon 201 of the surface of the wafer W by action of active species such as nitrogen radicals and nitrogen ions in the plasma. That is, the inner wall surface 207a of the trench 207 of the wafer W is nitrided to thereby form the dense liner SiN film 209 controlled to be extremely thin.

After forming the liner SiN film 209 as described above, the wafer W is unloaded from the plasma processing apparatus 100, and the process for one wafer W is completed.

<Plasma Nitriding Conditions>

It is preferable to use a gas containing a rare gas and nitrogen-containing gas as a processing gas of the plasma nitriding process. It is preferable that Ar gas is used as the rare gas and N₂ gas is used as the nitrogen-containing gas. In this case, a ratio of the volumetric flow rate of N₂ gas to the volumetric flow rate of the total processing gas (percentage of flow rate of N₂ gas/flow rate of total processing gas) is preferably in a range from 1% to 80%, and more preferably in a range from 10% to 30% in terms of forming a dense film with excellent oxygen barrier properties by increasing the nitrogen concentration in the liner SiN film 209. As the flow rate of the processing gas, for example, the flow rate of Ar gas preferably ranges from 100 mL/min (sccm) to 2000 mL/min (sccm), and more preferably ranges from 1000 mL/min (sccm) to 2000 mL/min (sccm). The flow rate of N₂ gas preferably ranges from 50 mL/min (sccm) to 500 mL/min (sccm), and more preferably ranges from 200 mL/min (sccm) to 500 mL/min (sccm). From the above ranges of the flow rates, it is preferable to set the flow rate ratio in the above range.

Further, the processing pressure is, e.g., preferably equal to or less than 187 Pa, more preferably in a range from 1.3 Pa to 187 Pa, and most preferably in a range from 1.3 Pa to 40 Pa in terms of forming a dense film with excellent oxygen barrier properties by increasing the nitrogen concentration in the liner SiN film 209. If the processing pressure exceeds 187 Pa in the plasma nitriding process, because the plasma contains less ions as active species for nitriding, the nitriding rate decreases and the dose of nitrogen also decreases.

Further, the microwave power density is preferably in a range from 0.7 W/cm² to 4.7 W/cm², and more preferably in a range from 1.4 W/cm² to 3.5 W/cm² in terms of enhancing the nitriding rate by efficiently generating active species in the plasma. Further, the microwave power density means the microwave power being supplied to each 1 cm² area of the microwave transmitting plate 28 (hereinafter, the same). For example, in case of processing the wafer W having a diameter of 200 mm or more, the microwave power is preferably in a range from 1000 W to 5000 W.

Further, the heating temperature of the wafer W is, as the temperature of the mounting table 2, for example, preferably in a range from 200° C. to 600° C., and more preferably in a range from 400° C. to 600° C.

Further, the processing time of the plasma nitriding process is not particularly limited if the liner SiN film 209 can be formed to have a desired thickness. For example, the processing time of the plasma nitriding process is preferably in a range from 1 second to 360 seconds, more preferably in a range from 90 seconds to 240 seconds, and most preferably in a range from 160 seconds to 240 seconds, for example, in terms of forming the liner SiN film 209 having a thickness of 1 to 10 nm, preferably, 2 to 5 nm by uniformly nitriding only the silicon surface of the inner wall surface 207a of the trench 207 in high concentration.

The above conditions are stored as a recipe in the storage unit 53 of the control unit 50. Further, the process controller 51 reads the recipe and transmits a control signal to each component (e.g., the gas supply unit 18, the vacuum pump 24, the microwave generator 39, the heater power supply 5a and the like) of the plasma processing apparatus 100, thereby achieving the plasma nitriding process under the desired conditions.

According to the plasma processing method of this embodiment, by performing the plasma nitriding process for a short period of time, it is possible to form the liner SiN film 209 having a thickness of 1 to 10 nm and serving as a barrier against diffusion of oxygen in a reaction gas in a thermal oxidation process at a high temperature, e.g., when the SiO₂ film is embedded in the trench by high temperature CVD (chemical vapor deposition). Since the thickness of the liner SiN film 209 formed in this way is small enough to cause little change in width and depth of the trench, it does not cause any impact such as restriction on the channel length of the device. Thus, in a manufacturing process of various semiconductor devices, by using the plasma processing method of this embodiment when the device isolation is performed by STI, thereby facilitating the response to miniaturization and increasing reliability of the semiconductor device.

### Second Embodiment

A plasma processing method of the second embodiment may be preferably applied, in the device isolation using STI including embedding an insulating film in a trench formed in silicon and planarizing the insulating film to form a device isolation film, to a case of nitriding the silicon of an inner wall surface of the trench by using a plasma before embedding the insulating film in the trench. The plasma processing method of this embodiment may include a plasma nitriding step of nitriding the inner wall surface of the trench by using a plasma of a processing gas containing a nitrogen-containing gas to form a silicon nitride film having a thickness of 1 to 10 nm before embedding the insulating film in the trench, and a plasma oxidation step of oxidizing the silicon nitride film by using a plasma of a processing gas containing an oxygen-containing gas to modify the silicon nitride film into a silicon oxynitride film. The plasma processing method of the second embodiment is different from that of the first embodiment in that the plasma oxidation is carried out after the plasma nitriding.

<Plasma Processing Apparatus>

In the plasma processing method of the second embodiment, a plasma processing apparatus 101 shown in FIG. 5 is used in addition to the plasma processing apparatus 100 shown in FIG. 1. FIG. 5 is a cross-sectional view schematically showing a configuration of the plasma processing apparatus 101. The plasma processing apparatus 101 shown in FIG. 5 is different from the plasma processing apparatus 100 of FIG. 1 in that the gas supply unit 18 includes an oxygen-containing gas supply source 19c instead of the nitrogen-containing gas supply source 19b. Thus, the following description will be given focusing on differences from the apparatus of FIG. 1. The same reference numerals are assigned to the same components as those of FIG. 1, and a description thereof will be omitted.

In the plasma processing apparatus 101 shown in FIG. 5, the gas supply unit 18 includes, as gas supply sources, e.g., the inert gas supply source 19a and the oxygen-containing gas supply source 19c. Further, the gas supply unit 18 has lines (e.g., gas lines 20a and 20c), flow rate controllers (e.g., mass flow controllers (MFCs) 21a and 21c), and valves (e.g., opening/closing valves 22a and 22c). Further, the gas supply unit 18 may further have, as a gas supply source (not shown) other than the above-mentioned gas supply sources, e.g., a purge gas supply source or the like used when changing the atmosphere in the processing chamber 1.

As an inert gas, e.g., a rare gas or the like may be used. As the rare gas, e.g., Ar gas, Kr gas, Xe gas, He gas or the like may be used. Among them, particularly, Ar gas is preferably used in terms of economic advantages. As an oxygen-containing gas used in the plasma oxidation, e.g., oxygen (O₂) gas, water vapor (H₂O), nitrogen monoxide (NO), nitrous oxide (N₂O) or the like may be used.

The inert gas and the oxygen-containing gas reach the gas inlet 15 from the inert gas supply source 19a and the oxygen-containing gas supply source 19c of the gas supply unit 18 through the gas lines 20a and 20c respectively, and are introduced into the processing chamber 1 from the gas inlet 15. Provided in the gas line 20a connected to the corresponding gas supply source are the mass flow controller 21a and a pair of the opening/closing valves 22a located at the upstream and downstream sides of the mass flow controller 21a. Similarly, provided in the gas line 20c connected to the corresponding gas supply source are the mass flow controller 21c and a pair of the opening/closing valves 22c located at the upstream and downstream sides of the mass flow controller 21c. By the configuration of the gas supply unit 18, it is possible to, e.g., switch the supplied gas or control the flow rate.

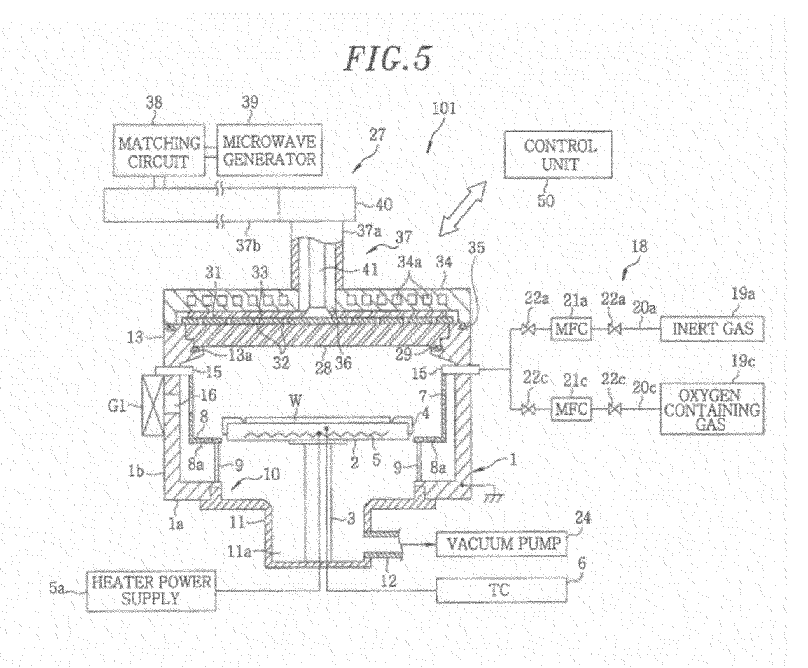

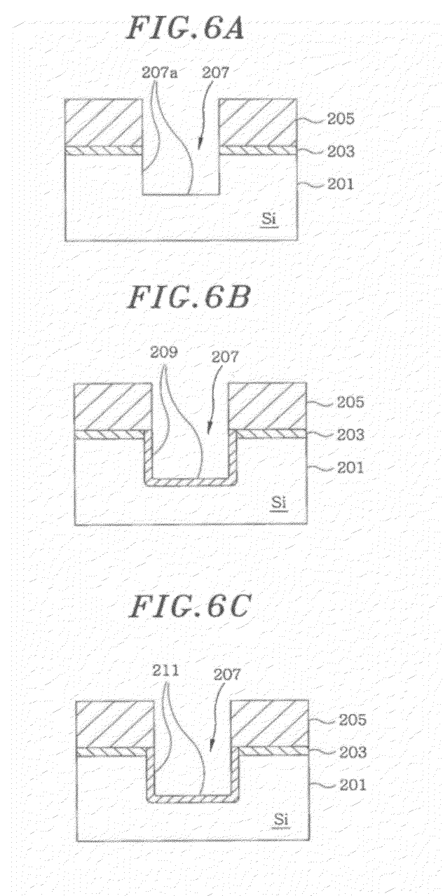

Next, the plasma processing method of this embodiment will be described with reference to FIGS. 6A to 6C. FIGS. 6A to 6C are cross-sectional views showing the vicinity of the surface of the wafer W for explaining steps of the plasma processing method of this embodiment.

<Plasma Nitriding Process>

In the plasma processing method of this embodiment, first, similarly to the first embodiment, a plasma nitriding process is performed on the wafer W to be processed. The wafer W serving as an object to be processed, as shown in FIG. 6A, has the silicon 201 having the trench 207 therein, similarly to the first embodiment. The inner wall surface 207a of the trench 207 of the silicon 201 is plasma nitrided to form the liner SiN film 209 (FIG. 6B). In this embodiment, since the plasma nitriding process can be performed exactly in the same way as the first embodiment, a description thereof will be omitted.

<Plasma Oxidation Process>

Then, a plasma oxidation process is performed on the wafer W having the liner SiN film 209 by using the plasma processing apparatus 101. Accordingly, as shown in FIG. 6C, the liner SiN film 209 is oxidized to form a liner SiON film 211.

<Plasma Oxidation Procedures>

Plasma oxidation procedures are as follows. First, while vacuum evacuating the processing chamber 1 of the plasma processing apparatus 101, e.g., Ar gas and O₂ gas are respectively introduced into the processing chamber 1 at predetermined flow rates from the inert gas supply source 19a and the oxygen-containing gas supply source 19c of the gas supply unit 18 through the gas inlet 15. Thus, the internal pressure of the processing chamber 1 is adjusted to a predetermined pressure.

Then, the microwave of a predetermined frequency (e.g., 2.45 GHz) generated in the microwave generator 39 is transmitted to the waveguide 37 via the matching circuit 38. The microwave transmitted to the waveguide 37 sequentially passes through the rectangular waveguide 37b and the coaxial waveguide 37a, and is supplied to the planar antenna 31 through the internal conductor 41. That is, the microwave propagates in a TE mode in the rectangular waveguide 37b, and the TE mode microwave is converted into a TEM mode microwave by the mode convertor 40. The TEM mode microwave propagates in the flat waveguide constituted by the cover member 34 and the planar antenna 31 through the coaxial waveguide 37a. Then, the microwave is radiated to the space above the wafer W in the processing chamber 1, through the microwave transmitting plate 28, from the microwave radiation holes 32 formed in a slot shape to pass through the planar antenna 31. The output of the microwave may be selected according to the purpose in a range from 1000 W to 5000 W in case of processing the wafer W having a diameter of, e.g., 200 mm or more.

An electromagnetic field is formed in the processing chamber 1 by the microwave radiated into the processing chamber 1 from the planar antenna 31 through the microwave transmitting plate 28, and the Ar gas and O₂ gas are converted into a plasma respectively. In this case, the microwave is radiated from the microwave radiation holes 32 of the planar antenna 31, thereby generating a plasma having a high density of approximately 1×10¹⁰ to 5×10¹²/cm³ and a low electron temperature of approximately 1.2 eV or less in the vicinity of the wafer W. In case of using the plasma generated as described above, it is possible to reduce damage to a base film due to ions or the like in the plasma. Further, a plasma oxidation process is performed on the wafer W by action of active species such as O₂⁺ ions or O(¹D₂) radicals in the plasma. In other words, the surface of the liner SiN film 209 formed in the trench of the wafer W is uniformly and extremely thinly oxidized to thereby form the liner SiON film 211 by formation of Si—O bonds instead of isolated N or Si—N bonds in an unstable state in the film. Further, it is preferable to perform the process under the plasma oxidation conditions that oxygen does not diffuse to an interface between the silicon and the liner SiN film 209. However, if the film thickness does not increase even though oxygen diffuses to the interface between Si and SiN, since the width and depth of the trench hardly change, it almost does not cause any impact such as restriction on the channel length of the device.

After modifying the liner SiN film 209 into the liner SiON film 211 by oxidation, the wafer W is unloaded from the plasma processing apparatus 101, and the process for one wafer W is completed.

<Plasma Oxidizing Conditions>

It is preferable to use a gas containing a rare gas and oxygen-containing gas as a processing gas of the plasma oxidation process. It is preferable that Ar gas is used as the rare gas and O₂ gas is used as the oxygen-containing gas. In this case, a ratio of the volumetric flow rate of O₂ gas to the volumetric flow rate of the total processing gas (percentage of flow rate of O₂ gas/flow rate of total processing gas) is preferably in a range from 1% to 80%, more preferably in a range from 1% to 70%, and most preferably in a range from 1% to 15% in terms of increasing the oxidation rate. As the flow rate of the processing gas, for example, the flow rate of Ar gas preferably ranges from 100 mL/min (sccm) to 2000 mL/min (sccm), and more preferably ranges from 1000 mL/min (sccm) to 2000 mL/min (sccm). The flow rate of O₂ gas preferably ranges, e.g., from 5 mL/min (sccm) to 250 mL/min (sccm), and more preferably ranges from 20 mL/min (sccm) to 250 mL/min (sccm). From the above ranges of the flow rates, it is preferable to set the flow rate ratio in the above range.

Further, the processing pressure is, e.g., preferably in a range from 1.3 Pa to 1000 Pa, more preferably in a range from 133 Pa to 1000 Pa, and most preferably in a range from 400 Pa to 667 Pa in terms of increasing the oxidation rate. If the processing pressure becomes less than 133 Pa in the plasma oxidation process, the number of oxygen ions increases, and the oxygen ions diffuse in the liner SiN film 209 and reach the interface between Si and SiN to oxidize the Si. Accordingly, it causes a substantial film growth, and the width and depth of the trench may change to cause an impact such as restriction on the channel length of the device. Further, if the processing pressure exceeds 1000 Pa, since the number of oxygen radicals increases, the liner SiN film 209 may not be sufficiently or uniformly oxidized. Accordingly, when the SiO₂ film is embedded in the trench 207 at a high temperature, the barrier properties against oxygen in the reaction gas are reduced.

Further, the microwave power density is preferably in a range from 0.7 W/cm² to 4.7 W/cm², and more preferably in a range from 1.4 W/cm² to 3.5 W/cm² in terms of efficiently generating oxidation active species such as O₂⁺ ions and O(¹D₂) radicals in the plasma. Further, the microwave power density means the microwave power being supplied to each 1 cm² area of the microwave transmitting plate 28 (hereinafter, the same). For example, in case of processing the wafer W having a diameter of 200 mm or more, the microwave power is preferably in a range from 1000 W to 5000 W.

Further, the heating temperature of the wafer W is, as the temperature of the mounting table 2, for example, preferably in a range from 200° C. to 600° C., and more preferably in a range from 400° C. to 600° C.

Further, the processing time of the plasma oxidation process is not particularly limited, but is for example preferably in a range from 1 second to 360 seconds, and more preferably in a range from 1 seconds to 60 seconds in terms of preventing oxygen from diffusing to the interface between Si and SiN or all of the nitride films from being modified into oxide films.

The above conditions are stored as a recipe in the storage unit 53 of the control unit 50. Further, the process controller 51 reads the recipe and transmits a control signal to each component (e.g., the gas supply unit 18, the vacuum pump 24, the microwave generator 39, the heater power supply 5a and the like) of the plasma processing apparatus 101, thereby achieving the plasma oxidation process under the desired conditions.

<Substrate Processing System>

Next, a substrate processing system capable of being suitably used in the plasma processing method of the second embodiment will be described. FIG. 7 schematically shows a configuration of a substrate processing system 200 configured such that the plasma nitriding process and the plasma oxidation process are continuously performed under the vacuum conditions. The substrate processing system 200 is configured as a cluster tool having a multi-chamber structure. The substrate processing system 200 includes, as main elements, four process modules 100a, 100b, 101a and 101b for performing various processes on the wafer W, a vacuum side transfer chamber 103 connected to the process modules 100a, 100b, 101a and 101b via gate valves G1, two load-lock chambers 105a and 105b connected to the vacuum side transfer chamber 103 via gate valves G2, and a loader unit 107 connected to the load-lock chambers 105a and 105b via gate valves G3.

The four process modules 100a, 100b, 101a and 101b may perform the same process or different processes on the wafer W. In this embodiment, in the process modules 100a and 100b, the inner wall surface of the trench of the silicon on the wafer W is plasma nitrided by using the plasma processing apparatus 100 (FIG. 1) to form the liner SiN film 209. In the process modules 101a and 101b, the liner SiN film 209 formed by the plasma nitriding is plasma oxidized by using the plasma processing apparatus 101 (FIG. 5).

Provided in the vacuum side transfer chamber 103 capable of being vacuum evacuated is a transfer unit 109 serving as a first substrate transfer unit performing delivery of the wafer W to/from the process modules 100a, 100b, 101a and 101b and the load-lock chambers 105a and 105b. The transfer unit 109 has a pair of transfer arms 111a and 111b arranged to face each other. The transfer arms 111a and 111b are configured to be extensible/contractible and rotatable around the same rotation axis. Further, forks 113a and 113b each mounting and holding the wafer W are provided at the tips of the transfer arms 111a and 111b, respectively. While the wafer W is mounted on the forks 113a and 113b, the transfer unit 109 performs transfer of the wafer W between the process modules 100a, 100b, 101a and 101b, or between the process modules 100a, 100b, 101a and 101b and the load-lock chambers 105a and 105b.

Provided in the load-lock chambers 105a and 105b are, respectively, mounting tables 106a and 106b each mounting the wafer W thereon. The load-lock chambers 105a and 105b are configured to be switchable between a vacuum state and an atmospheric open state. The delivery of the wafer W is carried out between the vacuum side transfer chamber 103 and an atmospheric side transfer chamber 119 (see below) through the mounting tables 106a and 106b of the load-lock chambers 105a and 105b.

The loader unit 107 has the atmospheric side transfer chamber 119 in which a transfer unit 117 is provided as a second substrate transfer unit performing transfer of the wafer W, three load ports LP arranged adjacent to the atmospheric side transfer chamber 119, and an orienter 121 disposed adjacent to the other side of the atmospheric side transfer chamber 119 to serve as a position measuring device measuring the position of the wafer W.

The atmospheric side transfer chamber 119 includes circulation equipment (not shown) forming a downflow of, e.g., a nitrogen gas or clean air to maintain a clean environment. The atmospheric side transfer chamber 119 is formed in a rectangular shape in the plan view and a guide rail 123 is provided in a longitudinal direction thereof. The transfer unit 117 is slidably supported on the guide rail 123. That is, the transfer unit 117 is configured to be movable in an X direction along the guide rail 123 by a drive mechanism (not shown). The transfer unit 117 has a pair of transfer arms 125a and 125b arranged vertically in two stages. Each of the transfer arms 125a and 125b is configured to be extensible/contractible and rotatable. Further, forks 127a and 127b each serving as a holding member for mounting and holding the wafer W are provided at the tips of the transfer arms 125a and 125b, respectively. While the wafer W is mounted on the forks 127a and 127b, the transfer unit 117 performs transfer of the wafer W between wafer cassettes CR of the load ports LP, the load-lock chambers 105a and 105b and the orienter 121.

The load ports LP are configured to mount the wafer cassettes CR thereon. The wafer cassettes CR are configured to accommodate a plurality of wafers W in multiple stages at equal intervals.

The orienter 121 includes a rotation plate 133 which is rotated by a drive motor (not shown), and an optical sensor 135 provided at an outer periphery of the rotation plate 133 to detect a peripheral portion of the wafer W.

<Wafer Processing Procedures>

In the substrate processing system 200, the plasma nitriding process and the plasma oxidation process are performed on the wafer W by the following steps. First, one wafer W is unloaded from the wafer cassettes CR of the load ports LP by using one of the forks 127a and 127b of the transfer unit 117 of the atmospheric side transfer chamber 119. After position alignment is performed in the orienter 121, the wafer W is loaded into the load-lock chamber 105a (or 105b). The load-lock chamber 105a (or 105b) in which the wafer W has been mounted on the mounting table 106a (or 106b) is evacuated to vacuum after closing the gate valve G3. Then, the gate valve G2 is opened, and the wafer W is transferred from the load-lock chamber 105a (or 105b) by the forks 113a and 113b of the transfer unit 109 in the vacuum side transfer chamber 103.

The wafer W transferred from the load-lock chamber 105a (or 105b) by the transfer unit 109 is first loaded into one of the process modules 100a and 100b. After closing the gate valve G1, the plasma nitriding process is performed on the wafer W.

Then, the gate valve G1 is opened, and the wafer W on which the liner SiN film 209 has been formed is loaded into one of the process modules 101a and 101b from the process module 100a (or 100b) in a vacuum state by the transfer unit 109. Then, after closing the gate valve G1, the plasma oxidation process is performed on the wafer W such that the liner SiN film 209 is modified into the liner SiON film 211.

Then, the gate valve G1 is opened, and the wafer W on which the liner SiON film 211 has been formed is unloaded from the process module 101a (or 101b) in a vacuum state and loaded into the load-lock chamber 105a (or 105b) by the transfer unit 109. Then, the processed wafer W is received in the wafer cassettes CR of the load ports LP in reverse order to the above, thereby completing processing of one wafer W in the substrate processing system 200. Further, arrangement of processing units in the substrate processing system 200 may be changed if processing can be efficiently performed. Further, the number of the process modules in the substrate processing system 200 may be five or more without being limited to four.

According to the plasma processing method of this embodiment, in the plasma process performed for a short period of time, it is possible to form the liner SiON film 211 having a thickness of 1 to 10 nm and serving as a barrier film against diffusion of oxygen in a thermal oxidation process at a high temperature almost without changing the depth or width of the trench. Thus, in a manufacturing process of various semiconductor devices, by using the plasma processing method of this embodiment when the device isolation is performed by STI, thereby increasing reliability of the semiconductor device while responding to miniaturization.

Other configurations and effects of this embodiment are similar to those of the first embodiment.

### EXPERIMENTAL EXAMPLE

Next, experimental data for confirming the effects of the present invention will be described.

### Experiment 1

The following processes A to D were performed on the silicon substrate. That is, after forming a SiN film, SiON film or SiO₂ film, a thermal oxidation process (hereinafter, may be referred to as “high temperature thermal oxidation process”) was performed at a temperature of 700° C., 750° C., 800° C. or 850° C. for 30 minutes for each case. The amount of increase in thickness of each film after the high temperature thermal oxidation process was measured to evaluate the effectiveness as a barrier film against the diffusion of oxygen.

[Process A; Formation of SiO₂ Film by Thermal Oxidation]

The thermal oxidation process was performed under the following conditions, thereby forming SiO₂ film a.

<Thermal Oxidation Conditions>

Processing temperature: 800° C.

Processing time: 1800 seconds

Film thickness (SiO₂): about 6 nm

[Process B; Formation of SION Film by Thermal Oxidation+Plasma Nitriding]

After the thermal oxidation process was performed under the same conditions as those of Process A, the plasma nitriding process was performed under the following conditions, thereby forming SiON film b.

<Plasma Nitriding Conditions>

Ar gas flow rate: 350 mL/min (sccm)

N₂ gas flow rate: 250 mL/min (sccm)

Processing pressure: 26 Pa

Temperature of mounting table: 500° C.

Microwave power: 2400 W (power density: 1.23 W/cm²)

Processing time: 240 seconds

Film thickness (SiON): about 6 nm

[Process C; Formation of SiN Film by Plasma Nitriding]

The plasma nitriding process was performed under the following conditions, thereby forming SiN film c.

<Plasma Nitriding Conditions>

Ar gas flow rate: 350 mL/min (sccm)

N₂ gas flow rate: 250 mL/min (sccm)

Processing pressure: 26 Pa

Temperature of mounting table: 500° C.

Microwave power: 2400 W (power density: 1.23 W/cm²)

Processing time: 240 seconds

Film thickness (SiN): about 4 nm

[Process D; Formation of SiON Film by Plasma Nitriding+Plasma Oxidation]

After the plasma nitriding process was performed under the same conditions as those of Process C, the plasma oxidation process was performed under the following conditions, thereby forming SiON film d.

<Plasma Oxidation Conditions>

Ar gas flow rate: 990 mL/min (sccm)

O₂ gas flow rate: 10 mL/min (sccm)

Processing pressure: 133 Pa

Temperature of mounting table: 500° C.

Microwave power: 4000 W (power density: 2.04 W/cm²)

Processing time: 30 seconds

Film thickness (SION): about 4 nm

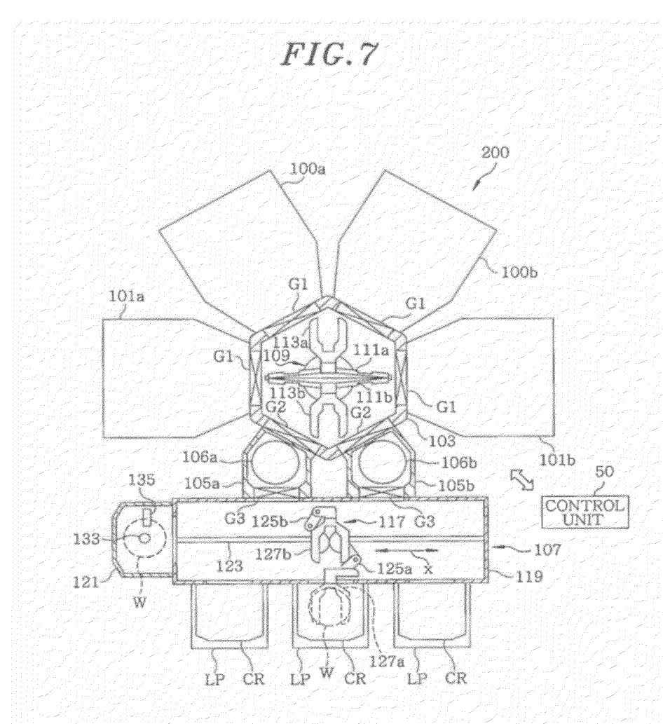

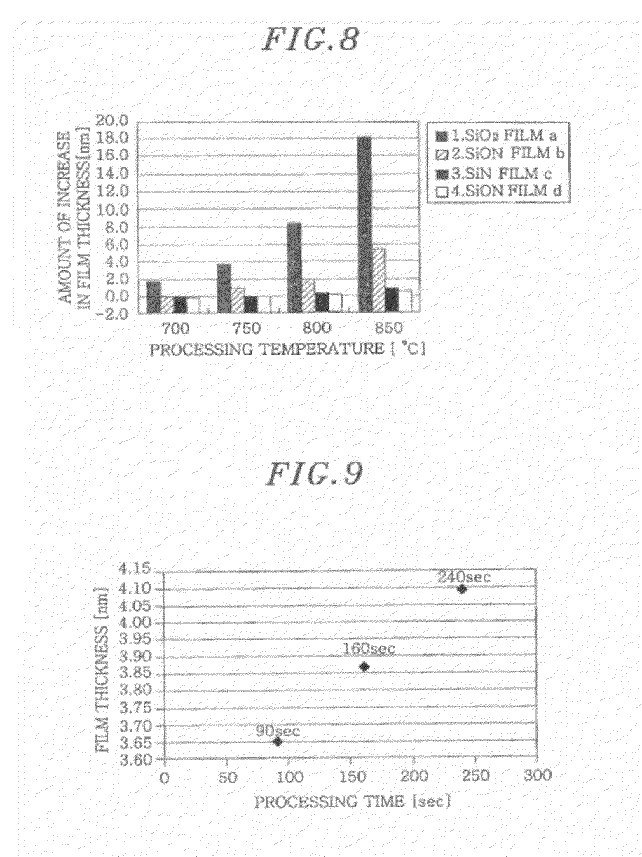

The experimental results are shown in FIG. 8. In FIG. 8, a vertical axis represents the amount of increase in film thickness after the high temperature thermal oxidation process (=film thickness after high temperature thermal oxidation−film thickness before high temperature thermal oxidation), and a horizontal axis represents the temperature of the high temperature thermal oxidation process. It can be seen from FIG. 8 that in case of the SiO₂ film a in Process A, as the temperature of the high temperature thermal oxidation process increases, the amount of increase in film thickness significantly increases. The tendency of the increase in film thickness due to the temperature rise in the high temperature thermal oxidation process was also observed in the SiON film b formed by Process B (plasma nitriding after thermal oxidation). On the other hand, the increase in film thickness due to the high temperature thermal oxidation process was not observed at all in the SiN film c formed by Process C (plasma nitriding), and the SiON film d formed by Process D (plasma oxidation after plasma nitriding).

### Experiment 2

The plasma nitriding process was performed on the silicon substrate by changing the processing time under the following conditions. After forming a SiN film, a high temperature thermal oxidation process was performed at a temperature of 700° C. 750° C., 800° C. or 850° C. for 30 minutes for each case. The amount of increase in thickness of each film after the high temperature thermal oxidation process was measured to evaluate the effectiveness as a barrier film against the diffusion of oxygen.

<Plasma Nitriding Conditions>

Ar gas flow rate: 350 mL/min (sccm)

N₂ gas flow rate: 250 mL/min (sccm)

Processing pressure: 26 Pa

Temperature of mounting table: 500° C.

Microwave power: 2400 W (power density: 1.23 W/cm²)

Processing time: 90 seconds, 160 seconds and 240 seconds

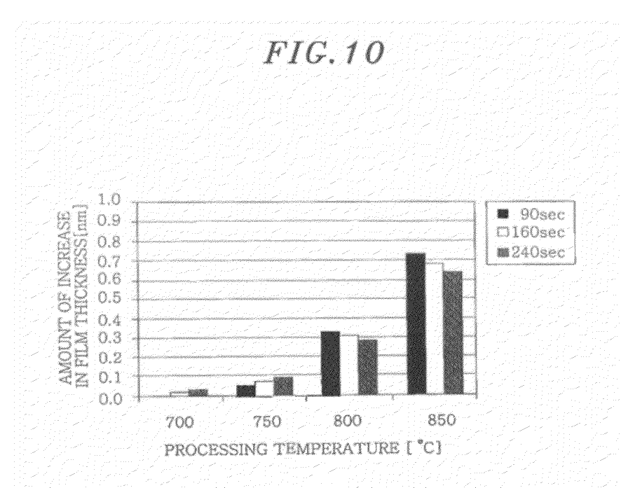

FIG. 9 illustrates a relationship between the processing time (horizontal axis) and the film thickness (vertical axis) of the SiN film. Further, FIG. 10 shows the amount of increase in film thickness according to the processing time. In FIG. 10, a vertical axis represents the amount of increase in film thickness after the high temperature thermal oxidation process (=film thickness after high temperature thermal oxidation−film thickness before high temperature thermal oxidation), and a horizontal axis represents the temperature of the high temperature thermal oxidation process. It can be seen from FIGS. 9 and 10 that as the processing temperature increases, the thickness of the SiN film increases, but the amount of Increase in film thickness due to the high temperature thermal oxidation process decreases conversely. It can be seen from these results that in case of forming the liner SiN film to have a thickness of, e.g., about 4 nm, in the above plasma nitriding conditions, the processing time preferably ranges from 90 seconds to 240 seconds, and more preferably ranges from 160 seconds to 240 seconds.

### Experiment 3

The plasma nitriding process was performed on the silicon substrate by changing the processing pressure under the following conditions. After forming a SiN film, a high temperature thermal oxidation process was performed at a temperature of 850° C. for 30 minutes for each case. The amount of increase in thickness of each film after the high temperature thermal oxidation process was measured to evaluate the effectiveness as a barrier film against the diffusion of oxygen.

<Plasma Nitriding Conditions>

Ar gas flow rate: 350 mL/min (sccm)

N₂ gas flow rate: 250 mL/min (sccm)

Processing pressure: 26 Pa, 667 Pa, 1066 Pa

Temperature of mounting table: 500° C.

Microwave power: 2400 W (power density: 1.23 W/cm²)

Processing time: 240 seconds

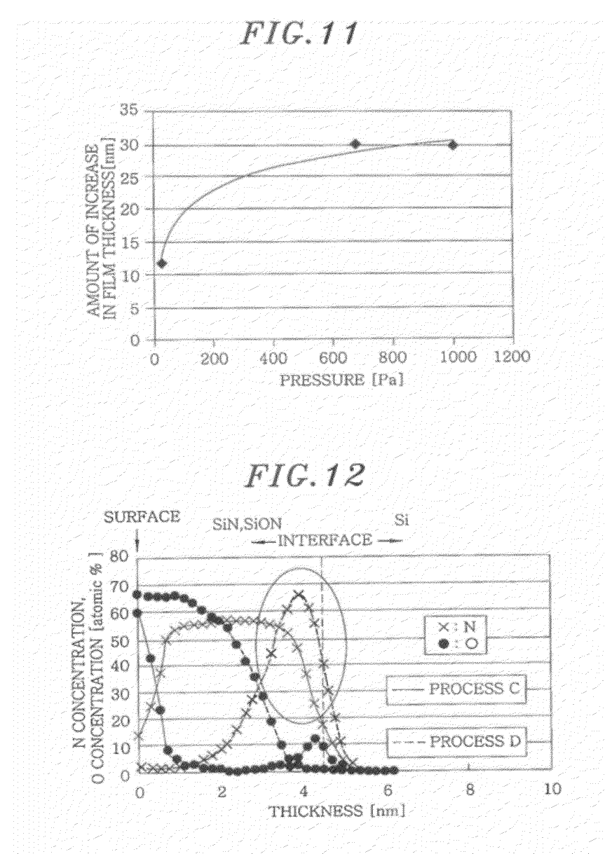

FIG. 11 shows the amount of increase in film thickness according to the processing pressure. In FIG. 11, a vertical axis represents the amount of increase in film thickness after the high temperature thermal oxidation process (=film thickness after high temperature thermal oxidation−film thickness before high temperature thermal oxidation), and a horizontal axis represents the processing pressure. It can be seen from FIG. 11 that as the processing temperature increases, the amount of increase in film thickness due to the high temperature thermal oxidation process increases. Thus, it was confirmed that it is more preferable as the processing pressure of the plasma nitriding process decreases. For example, in order to suppress the amount of increase in film thickness not to exceed 20 nm, it can be seen that in the above plasma nitriding conditions, the processing pressure is preferably equal to or less than 187 Pa, more preferably in a range from 1.3 Pa to 187 Pa, and most preferably in a range from 1.3 Pa to 40 Pa.

### Experiment 4

X-ray photoelectron spectroscopy (XPC) analysis was performed on the SiN film c and the SiON film d obtained in Process C and Process D of Experiment 1. The chemical composition profiles of the SiN film c and the SiON film d measured by the XPC analysis were illustrated together in FIG. 12. In FIG. 12, a vertical axis represents the nitrogen concentration and oxygen concentration (atomic percent for both), and a horizontal axis represents the depth from the film surface (0 nm). It was confirmed that nitrogen is almost evenly distributed in the SiN film c, whereas a peak of nitrogen is shifted to the vicinity of the interface with Si in the SiON film d. In the SiON film d formed by Process D, since the peak of nitrogen is present in the vicinity of the interface, it was assumed that in the high temperature thermal oxidation process, oxygen is blocked in a region with high nitrogen concentration in diffusing to the Si interface and prevented from being bound to Si, so that excellent barrier properties can be obtained.

It was confirmed from the above experimental results that in Process C in which the plasma nitriding process corresponding to the first embodiment of the present invention was performed, and Process D in which the plasma oxidation process, after the plasma nitriding process, corresponding to the second embodiment of the present invention was performed, both of the SiN film c and the SiON film d serve as excellent barrier films, and it is possible to effectively prevent the diffusion of oxygen in the high temperature thermal oxidation process. The barrier function against the diffusion of oxygen will be understood by comparison with Process B rather than a mere difference in film composition (whether it is SiN or SiON).

[Application Example to STI Process]

Next, procedures for forming a device isolation structure by an STI process by using the plasma processing method in accordance with the present invention will be described with an example. FIGS. 13 to 18 are cross-sectional views of the vicinity of the surface of the wafer showing main steps of the STI process.

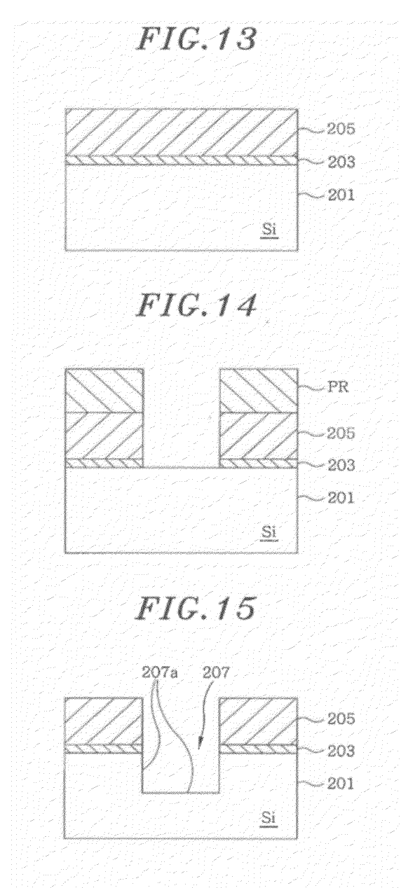

First, as shown in FIG. 13, the wafer W in which the silicon (silicon layer or silicon substrate) 201, the silicon oxide (SiO₂) film 203, and the silicon nitride (SiN) film 205 are sequentially stacked is prepared. Then, a photoresist layer PR is provided on the SiN film 205. Further, although not shown, the photoresist layer PR is patterned by photolithography to expose a region of the SiN film 205 where a trench is to be formed. Further, using the patterned photoresist layer PR as a mask, as shown in FIG. 14, the SiN film 205 and the SiO₂ film 203 are sequentially dry etched to expose the surface of the silicon 201.

Then, after the photoresist layer PR is removed, the exposed surface of the silicon 201 is dry etched using the SiN film 205 as a mask, thereby forming the trench 207 as shown in FIG. 15.

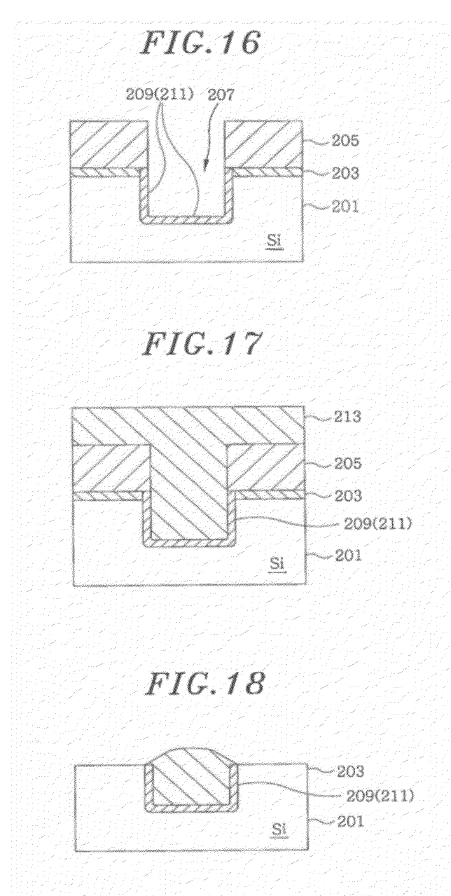

Next, the plasma nitriding process is performed on the inner wall surface 207a of the trench 207 by the method described in the first embodiment to thereby form the liner SiN film 209 as shown in FIG. 16. Further, after the plasma nitriding process, the plasma oxidation process may be performed by the method described in the second embodiment such that the liner SiON film 211 is formed. The thickness of the liner SiN film 209 (or the liner SiON film 211) preferably ranges from 1 to 10 nm, and more preferably ranges from 2 to 5 nm.

Then, as shown in FIG. 17, a buried insulating film 213 is formed from the top of the liner SiN film 209 (or the liner SiON film 211) to fill up the trench 207. The buried insulating film 213 is typically a SiO₂ film formed by thermal oxidation at a high temperature. In the subsequent step, the liner SiN film 209 (or the liner SiON film 211) functions as a barrier film to prevent oxygen from entering into the silicon 201 from the buried insulating film 213.

Then, although not shown, CMP is performed to planarize an upper portion of the buried insulating film 213 until the SiN film 205 is exposed. Further, the SiN film 205, the SiO₂ film 203 and an upper portion of the buried insulating film 213 are removed by wet etching to thereby form a desired device isolation structure as shown in FIG. 18. In the device isolation structure formed in this way, since the liner SiN film 209 (or the liner SiON film 211) becomes a barrier film against the diffusion of oxygen, it is possible to prevent the silicon surrounding the trench 207 from being oxidized. As a result, it is possible to suppress an increase of the buried insulating film 213, and enhance the reliability of the device isolation structure while responding to the miniaturization in design. Further, it is possible to improve the reliability of the semiconductor device.

Further, the embodiments of the present invention have been described, but the present invention is not limited to the above-described embodiments, and various modifications may be made. For example, although the RLSA type microwave plasma processing apparatus has been used in the plasma nitriding process and the plasma oxidation process in the above-described embodiments, other types of plasma processing apparatuses such as an inductively coupled plasma (ICP) processing apparatus, an electron cyclotron resonance (ECR) plasma processing apparatus, a surface reflected wave plasma processing apparatus, and a magnetron plasma processing apparatus may be used.

Further, as a substrate serving as an object to be processed, without being limited to a semiconductor wafer, a substrate having a silicon layer with a trench formed therein may be used. For example, a substrate for flat panel displays, a substrate for solar cells or the like may be used as an object to be processed.

While the invention has been shown and described with respect to the embodiments, it will be understood by those skilled in the art that various changes and modification may be made without departing from the scope of the invention as defined in the following claims.

What is claimed is:

1. A plasma processing method for use in device isolation by shallow trench isolation in which an insulating film is embedded in a trench formed in silicon and the insulating film is planarized to form a device isolation film, the method comprising:
a plasma nitriding the silicon of an inner wall surface of the trench by using a plasma before embedding the insulating film in the trench,
wherein the plasma nitriding is performed by using a plasma of a processing gas containing a nitrogen-containing gas under conditions in which a processing pressure ranges from 1.3 Pa to 187 Pa and a ratio of a volumetric flow rate of the nitrogen-containing gas to a volumetric flow rate of the entire processing gas ranges from 1% to 80% such that a silicon nitride film is formed on the inner wall surface of the trench to have a thickness of 1 to 10 nm.

2. The plasma processing method of claim 1, wherein the processing pressure in said plasma nitriding ranges from 1.3 Pa to 40 Pa.

3. The plasma processing method of claim 1, further comprising, after said plasma nitriding, oxidizing the silicon nitride film by using a plasma of a processing gas containing an oxygen-containing gas to modify the silicon nitride film into a silicon oxynitride film.

4. The plasma processing method of claim 2, further comprising, after said plasma nitriding, oxidizing the silicon nitride film by using a plasma of a processing gas containing an oxygen-containing gas to modify the silicon nitride film into a silicon oxynitride film.

5. The plasma processing method of claim 3, wherein in said plasma oxidation, a processing pressure ranges from 1.3 Pa to 1000 Pa, and a ratio of a volumetric flow rate of the oxygen-containing gas to a volumetric flow rate of the entire processing gas ranges from 1% to 80%.

6. The plasma processing method of claim 4, wherein in said plasma oxidation, a processing pressure ranges from 1.3 Pa to 1000 Pa, and a ratio of a volumetric flow rate of the oxygen-containing gas to a volumetric flow rate of the entire processing gas ranges from 1% to 80%.

7. The plasma processing method of claim 3, wherein said plasma nitriding and said plasma oxidation are performed by using a plasma processing apparatus which generates a plasma by introducing a microwave into a processing chamber through a planar antenna having holes.

8. The plasma processing method of claim 6, wherein said plasma nitriding and said plasma oxidation are performed by using a plasma processing apparatus which generates a plasma by introducing a microwave into a processing chamber through a planar antenna having holes.

9. A device isolation method comprising:
forming a trench in silicon;
embedding an insulating film in the trench;
planarizing the insulating film to form an device isolation film; and
before said embedding the insulating film in the trench, a plasma nitriding an inner wall surface of the trench by using a plasma of a processing gas containing a nitrogen-containing gas under conditions in which a processing pressure ranges from 1.3 Pa to 187 Pa and a ratio of a volumetric flow rate of the nitrogen-containing gas to a volumetric flow rate of the entire processing gas ranges from 1% to 80% such that a silicon nitride film is formed to have a thickness of 1 to 10 nm.

10. The device isolation method of claim 9, wherein the processing pressure in said plasma nitriding ranges from 1.3 Pa to 40 Pa.

11. The device isolation method of claim 9, further comprising, after said plasma nitriding, a plasma oxidation step of oxidizing the silicon nitride film by using a plasma of a processing gas containing an oxygen-containing gas to modify the silicon nitride film into a silicon oxynitride film.

12. The device isolation method of claim 11, wherein in said plasma oxidation, a processing pressure ranges from 1.3 Pa to 1000 Pa, and a ratio of a volumetric flow rate of the oxygen-containing gas to a volumetric flow rate of the entire processing gas ranges from 1% to 80%.

13. The device isolation method of claim 11, wherein said plasma nitriding and said plasma oxidation are performed by using a plasma processing apparatus which generates a plasma by introducing a microwave into a processing chamber through a planar antenna having holes.

14. The device isolation method of claim 10, further comprising, after said plasma nitriding, oxidizing the silicon nitride film by using a plasma of a processing gas containing an oxygen-containing gas to modify the silicon nitride film into a silicon oxynitride film.

15. The device isolation method of claim 14, wherein in said plasma oxidation, a processing pressure ranges from 1.3 Pa to 1000 Pa, and a ratio of a volumetric flow rate of the oxygen-containing gas to a volumetric flow rate of the entire processing gas ranges from 1% to 80%.

16. The device isolation method of claim 15, wherein said plasma nitriding and said plasma oxidation are performed by using a plasma processing apparatus which generates a plasma by introducing a microwave into a processing chamber through a planar antenna having holes.
